(19) United States
(12) Patent Application Publication
(10) Pub. No.: US 2025/0364966 A1
(43) Pub. Date: Nov. 27, 2025

(54) PIEZOELECTRIC MATERIALS, DEVICES AND METHODS OF FABRICATING SAID DEVICES

(71) Applicant: Robert Bosch GmbH, Stuttgart (DE)

(72) Inventors: Mordechai KORNBLUTH, Brighton, MA (US); Sanjay GOPALAN, Richardson, TX (US); Christoph SCHELLING, Stuttgart (DE); Simon SCHNEIDER, Karlsruhe (DE); Daniil KITCHAEV, Brookline, MA (US); Daniel PANTEL, Mundelsheim (DE)

(21) Appl. No.: 18/672,518

(22) Filed: May 23, 2024

(51) Int. Cl. H03H 9/02; C01B 21/06; H03H 3/02; H03H 9/17; H03H 9/56

(52) U.S. Cl. CPC H03H 9/02031; C01B 21/0602; H03H 3/02; H03H 9/173; H03H 9/174; H03H 9/175; H03H 9/176; H03H 9/562; H03H 9/564; C01P 2002/30; C01P 2002/52; C01P 2006/40; C01P 2006/90

(57) ABSTRACT

Disclosed herein are aluminum nitride (AlN) piezoelectric materials, piezoelectric devices and related methods of fabricating said devices. The piezoelectric materials comprise a doping element that enhances the piezoelectric properties of the material and a stiffening element, which enhances the mechanical properties of the piezoelectric material. The incorporation of an enhancing and stiffening element to binary alloys of AlN, results in a quaternary AlN alloy, which reduces current trade-offs between the piezoelectric tensor component (e₃₃), and stiffness of the material (C₃₃).

### TECHNICAL FIELD

The present disclosure relates to devices comprising piezoelectric materials and methods of fabricating said devices. More specifically, the disclosure relates to bulk acoustic wave (BAW) resonators comprising piezoelectric thin films.

### BACKGROUND

The advancement of modern wireless communication systems requires high-performance filters and frequency reference elements with high operation frequency, miniature size, and low cost. Bulk acoustic wave (BAW) resonators are well suited for mobile telecommunication systems operating at high frequencies from 0.5 to 50 GHz and have been actively developed for the past twenty years. A BAW resonator typically consists of a layer of piezoelectric thin film sandwiched between two thin metal electrodes. When an alternating electrical voltage is applied between the two electrodes, the consequent electric field between the electrodes interacts with piezoelectric material to generate acoustic waves within the piezoelectric material.

A piezoelectric material is a material that couples mechanical strain and electric fields. Due to a polarizable non-symmetric atomic structure, an applied electric field will induce a mechanical strain, and conversely a mechanical strain will induce an electric field in the material. As noted above, in a BAW resonator, a microscale crystal is sandwiched by electrodes, where an incoming electromagnetic wave will create a voltage differential if it matches the resonance frequency of the resonator.

In a longitudinal resonator, the figure of merit is given by kₜ²Q, where Q is the quality factor of the resonator, and kₜ² is the intrinsic electromechanical coupling coefficient, which is

$$\frac{{e}_{33}^{2}}{{e}_{33}^{2} + {ϵ}_{33} {C}_{33}^{E}} .$$

These symbols relate the coupling between electric and stress fields and forces, as follows:

| Basic macroscopic | |
|---|---|
| equations | Description |
| \vec{σ} = Ĉ^{E}\vec{ε} − ê^{T}\vec{E} | Stress-strain relation (stiffness) including |
| | piezoelectric effect |
| \vec{D} = ê\vec{ε} + \hat{ϵ}\vec{E} | Displacement field, including piezoelectric effect |

where \vec{σ} is the stress, Ĉ^{E} is the stiffness tensor under constant electric field, \vec{ε} is the strain field, ê is the piezoelectric tensor, \vec{E} is the electric field, \vec{D} is the displacement field, and e is the dielectric tensor.

One key material for piezoelectric resonators is wurtzite aluminum nitride (AlN). It was discovered in the last several years that alloying or doping AlN with scandium to form Al₁₋ₓScₓN yields an improved piezoelectric material. The scandium both lowers components of the stiffness tensor (Ĉ) and raises the piezoelectric tensor component (e₃₃), both of which lead to a greater value of kₜ. A high value of kₜ is desired because it reflects a higher quantity of electromagnetic wave that is converted to mechanical energy. However, in certain applications or devices, the doped piezoelectric material is desired to have a high speed of sound (vₛ) which can be approximately given by the term

$$\sqrt{\frac{{C}_{33}}{ρ}} .$$

The resonance frequency of the piezoelectric film is approximately given by f=vₛ/d, where f is the resonance frequency, vₛ is the speed of sound in the material, and d is the thickness of the film. Generally, it is more difficult to produce a thinner film than to produce a thicker film of comparable quality and relative thickness tolerance. Therefore, if a particular resonance frequency (f) is required for the piezoelectric material, and a high value of film thickness, (d) is required (which is easy to fabricate), and therefore a relatively higher value of vₛ is desired. Therefore, to make it easier for commercially fabricating piezoelectric films, it will be ideal to have higher value of

$$\sqrt{\frac{{C}_{33}}{ρ}} ,$$

which can be achieved with dopants which lead to high C₃₃ values.

Nitrides containing elements like Sc, Cr, Y and Yb when alloyed into AlN enhance the piezoelectricity of the material but concomitantly significantly soften it mechanically. Therefore, a ternary alloy of AlN with the above piezoelectric enhancers will yield an improved piezoelectric coefficient and electromechanical coupling constant but also will result in significantly lower stiffness of the alloy.

In light of the above drawbacks, there is a need for a piezoelectric AlN material, which has enhanced piezoelectric properties, but also improved mechanical properties, such that the mechanical stability of the material is not compromised, particularly during fabrication as a thin film material.

### SUMMARY

Disclosed herein are aluminum nitride (AlN) piezoelectric materials, piezoelectric devices and related methods of fabricating said devices. The disclosed piezoelectric materials comprise a first doping element that enhances the piezoelectric properties of the material and an additional stiffening element, which enhances the mechanical properties of the piezoelectric material. The incorporation of a piezoelectric enhancer and stiffening element to binary alloys of AlN, results in a quaternary AlN alloy, which reduces current trade-offs between the piezoelectric tensor component (e₃₃), and stiffness of the material (C₃₃).

In one embodiment, a piezoelectric device is disclosed, such as a be a bulk acoustic wave (BAW) resonator. The BAW resonator can be a film bulk acoustic resonator (FBAR). An FBAR piezoelectric device comprises a substrate, a piezoelectric layer, a first electrode layer and a second electrode layer. The piezoelectric layer comprises a quaternary alloy, Al_{1-x-y}TₓM_{y}N, wherein 0<x+y<0.5. The element T can be selected from at least one of Sc, Cr, Y, and Yb and the element M can be selected from at least one of B, In, and Ga.

In certain embodiments, the piezoelectric layer comprises Al_{1-x-y}YₓB_{y}N and/or Al_{1-x-y}CrₓB_{y}N and/or Al_{1-x-y}ScₓB_{y}N.

Also disclosed are methods for fabricating a doped piezoelectric device. The method comprises the steps of providing a substrate and depositing a doped piezoelectric material on the substrate. The doped piezoelectric material comprises Al_{1-x-y}TₓM_{y}N, wherein 0<x+y<0.5, T is selected from Sc, Cr, Y, and Yb and M is selected from B, In, and Ga.

The doped piezoelectric material can be deposited by sputter deposition, molecular beam epitaxy (MBE), or metalorganic chemical vapor deposition (MOCVD). In one embodiment, the sputter deposition process comprises single target sputtering or multi-target sputtering.

### Selected Definitions and Nomenclature

As used herein, the terms “alloy”, “alloyed”, “alloying” and “dopant”, “doped”, or “doping” can be used interchangeably to refer to the addition of elements within the piezoelectric materials disclosed herein. The terms “alloy” or “dopant” are not intended to limit the specific atomic amount of an element that is added or incorporated into the piezoelectric materials disclosed herein.

As used herein “wurtzite” phase crystal structure refers to a structure in which the anions have a hexagonal close packed arrangement with the cations occupying one type of tetrahedral hole.

The term “about” is used in conjunction with numeric values to include normal variations in measurements as expected by persons skilled in the art, and is understood to have the same meaning as “approximately” and to cover a typical margin of error, such as ±15%, ±10%, ±5%, ±1%, ±0.5%, or even ±0.1% of the stated value. The term “about” also encompasses amounts that differ due to different equilibrium conditions for a composition resulting from a particular initial composition. Whether or not modified by the term “about,” the claims include equivalents to the quantities.

It should be noted that, as used in this specification and the appended claims, the singular forms “a,” “an,” and “the” include plural referents unless the content clearly dictates otherwise. Thus, for example, reference to a composition containing “a compound” includes having two or more compounds that are either the same or different from each other. It should also be noted that the term “or” is generally employed in its sense including “and/or” unless the content clearly dictates otherwise. As used herein, “and/or” refers to and encompasses any and all possible combinations of one or more of the associated listed items, as well as the lack of combinations when interpreted in the alternative (“or”).

In the interest of brevity and conciseness, any ranges of values set forth in this specification contemplate all values within the range and are to be construed as support for claims reciting any sub-ranges having endpoints which are real number values within the specified range in question. By way of a hypothetical illustrative example, a disclosure in this specification of a range of from 1 to 5 shall be considered to support claims to any of the following ranges: 1-5; 1-4; 1-3; 1-2; 2-5; 2-4; 2-3; 3-5; 3-4; and 4-5.

The term “substantially” is utilized herein to represent the inherent degree of uncertainty that can be attributed to any quantitative comparison, value, measurement, or other representation. The term “substantially” is also utilized herein to represent the degree by which a quantitative representation can vary from a stated reference without resulting in a change in the basic function of the subject matter at issue.

The term “comprise,” “comprises,” and “comprising” as used herein, specify the presence of the stated features, integers, steps, operations, elements, and/or components, but do not preclude the presence or addition of one or more other features, integers, steps, operations, elements, components, and/or groups thereof.

As used herein, the transitional phrase “consisting essentially of” means that the scope of a claim is to be interpreted to encompass the specified materials or steps recited in the claim and those that do not materially affect the basic and novel characteristic(s) of the claimed invention. Thus, the term “consisting essentially of” when used in a claim of this invention is not intended to be interpreted to be equivalent to “comprising.”

As used herein, the terms “increase,” “increasing,” “increased,” “enhance,” “enhanced,” “enhancing,” and “enhancement” (and grammatical variations thereof) describe an elevation of at least about 1%, 5%, 10%, 15%, 25%, 50%, 75%, 100%, 150%, 200%, 300%, 400%, 500% or more as compared to a control.

As used herein, the terms “reduce,” “reduced,” “reducing,” “reduction,” “diminish,” and “decrease” (and grammatical variations thereof), describe, for example, a decrease of at least about 1%, 5%, 10%, 15%, 20%, 25%, 35%, 50%, 75%, 80%, 85%, 90%, 95%, 97%, 98%, 99%, or 100% as compared to a control. In particular embodiments, the reduction can result in no or essentially no (i.e., an insignificant amount, e.g., less than about 10% or even 5% or even 1%) detectable activity or amount.

The terms “preferred” and “preferably” refer to embodiments that may afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the present disclosure.

The terms “over,” “under,” “between,” and “on” as used herein refer to a relative position of one component or material with respect to other components or materials where such physical relationships are noteworthy. For example, in the context of materials, one material or material disposed over or under another may be directly in contact or may have one or more intervening materials. Moreover, one material disposed between two materials or materials may be directly in contact with the two layers or may have one or more intervening layers. In contrast, a first material or material “on” a second material or material is in direct contact with that second material/material. Similar distinctions are to be made in the context of component assemblies.

As used throughout this description, and in the claims, a list of items joined by the term “at least one of” or “one or more of” can mean any combination of the listed terms. For example, the phrase “at least one of X, Y or Z” can mean X; Y; Z; X and Y; X and Z; Y and Z; or X, Y and Z

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions.

### BRIEF DESCRIPTION OF THE DRAWINGS

FIG. 1 depicts a cross-sectional view of an embodiment of a piezoelectric device having a piezoelectric layer deposited thereon, in accordance with embodiments disclosed herein.

FIG. 2 depicts a cross-sectional view of an embodiment of a piezoelectric device having a piezoelectric layer deposited thereon, in accordance with embodiments disclosed herein.

FIG. 3 depicts a cross-sectional view of a piezoelectric device having a piezoelectric layer deposited thereon, in accordance with embodiments disclosed herein.

FIG. 4 shows graphical results of relation between dopant addition x, y, to piezoelectric material AlN and the resulting kₜ² and vₛ values.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative bases for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical application. Various combinations and modifications of the features consistent with the teachings of this disclosure, however, could be desired for particular applications or implementations.

Disclosed herein are aluminum nitride (AlN) piezoelectric materials, piezoelectric devices and related methods of fabricating said devices. The piezoelectric materials comprise a doping element that enhances the piezoelectric properties of the material and a stiffening element, which enhances the mechanical properties of the piezoelectric material. The incorporation of an enhancing and stiffening element to binary alloys of AlN, results in a quaternary AlN alloy, which reduces current trade-offs between the piezoelectric tensor component (e₃₃), and stiffness of the material (C₃₃).

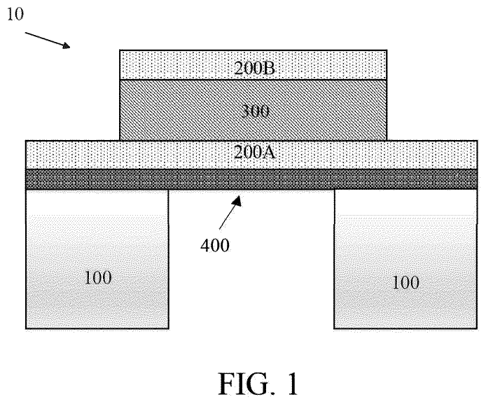

In one embodiment, a piezoelectric device is disclosed. The piezoelectric device can be a bulk acoustic wave (BAW) resonator. The BAW resonator can be a film bulk acoustic resonator (FBAR). Shown in FIGS. 1-3 are various embodiments of an FBAR piezoelectric device 10, comprising a substrate 100, a piezoelectric layer 300, a first electrode layer 200A and a second electrode layer 200B.

The piezoelectric layer 300 comprises a quaternary alloy, Al_{1-x-y}TₓM_{y}N, wherein 0<x+y<0.5. The element T can be selected from at least one of Sc, Cr, Y, and Yb and the element M can be selected from at least one of B, In, and Ga. In this piezoelectric layer 300, T is incorporated as the piezoelectric enhancing dopant (or alloy), and M is incorporated for purposes of increasing the stiffness and mechanical properties of the alloyed piezoelectric material.

In one embodiment, the piezoelectric material has a wurtzite crystal structure, wherein x<0.5 and y<0.5. In other embodiments, the combination of x and y totals 0.5 or less. 0.4 or less, 0.3 or less, 0.2 or less, or 0.1 or less. In other words, the combination of the enhancing dopant and the stiffening dopant (M and T combined) in the AlN alloy of layer 300, has an atomic percent of 50% or less, 40% or less, 20% or less, or 10% or less. In one embodiment, the atomic content of the enhancing dopant, M, can be 1-50%, or 1-45%, or 1-35%, or 1-30%, or 1-25%, or 1-20%. In further embodiments, the enhancing dopant M is incorporated in an atomic content of 10-50%, or 20-50%, or 30-50%, or 40-50%. The atomic content of the stiffening dopant, T, is 1-40%, or 1-35%, or 1-30%, or 1-25%.

In one embodiment, the piezoelectric layer material incorporates Al_{1-x-y}TₓM_{y}N, where x and y are equal, resulting in Al₁₋₂ₓTₓMₓN.

In certain embodiments, the piezoelectric layer comprises Al_{1-x-y}YₓB_{y}N and/or Al_{1-x-y}CrₓB_{y}N and/or Al_{1-x-y}ScₓB_{y}N.

In one embodiment, the piezoelectric material of layer 300 has an electromechanical coupling constant, kₜ², where kₜ² is about 0.1-0.8., and a

$$\sqrt{\frac{{C}_{33}}{ρ}}$$

value of about 7,000-10,000 m/s, and a stiffness coefficient, C₃₃, of about 100-400 GPa. In further embodiments, the kₜ² value is about 0.2-0.7, or 0.3-0.6, or 0.4-0.5, or 0.2-0.8, or 0.3-0.8, or 0.4-0.8, or 0.5-0.8, or 0.6-0.8, or 0.7-0.8, or any value or range therebetween. In other embodiments, the

$$\sqrt{\frac{{C}_{33}}{ρ}}$$

value is about 7,500-10,000, or 8,000-10,000, or 8,500-10,000, or 9,000-10,000, or 7, 000-9,500, or 7,500-9,000, or 8,000-8,500, or any value or range therebetween. In further embodiments, the stiffness coefficient, C₃₃, has a value of about 150-350 GPa, or 200-300 GPa, or any value or range therebetween.

Piezoelectric layer 300 has a thickness of about 50-2000 nm, or 100-2000 nm, or 200-2000 nm, or 300-2000 nm, or 400-2000 nm, or 500-2000 nm, or 600-2000 nm, or 700-2000 nm, or 800-2000 nm, or 900-2000 nm, or 50-1000 nm, or 100-1000 nm, or 200-1000 nm, or 300-1000 nm, or 400-1000 nm, or 500-1000 nm, or 600-1000 nm, or 700-1000 nm, or 800-1000 nm, or 900-1000 nm. In certain embodiments, the piezoelectric layer 300 has a thickness of about 50-500 nm, or 100-400 nm, or 200-300 nm, or any value or range therebetween.

The substrate layer 100 can be a ceramic material such as alumina, sapphire, glass, single-crystalline or polycrystalline aluminum nitride, gallium nitride, silicon carbide or a silicon, Si (100) or Si (111) substrate. Silicon wafers are the most common substrate for BAW devices due to their scalability towards mass manufacturing and compatibility with various manufacturing process steps.

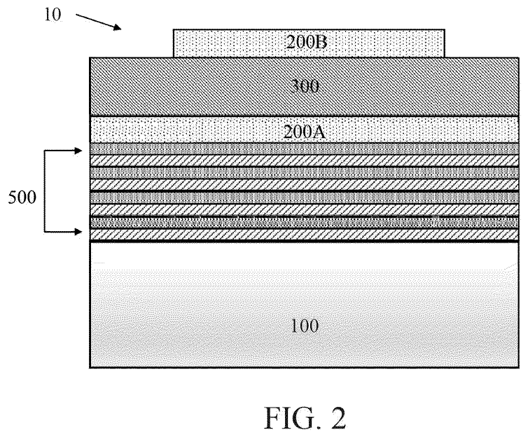

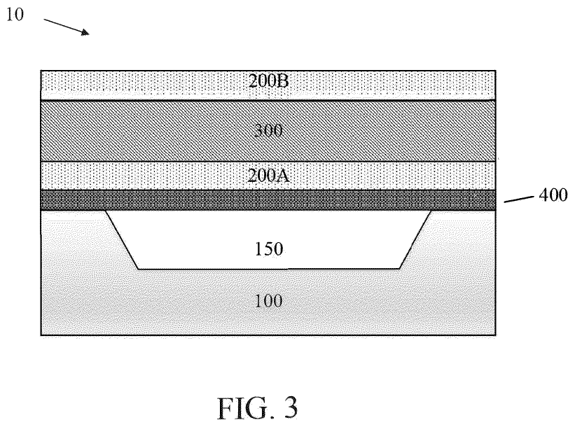

In certain embodiments, portions of the substrate layer 100 can be removed. such as the configuration shown in FIG. 1. This removal step and geometry will depend on the type of piezoelectric device being fabricated. The depicted embodiment of FIG. 1 is referred to as a membrane FBAR resonator. In other embodiments, the device is an air gap FBAR, such as the device depicted in FIG. 3, which incorporates an air gap 150 between the substrate and the optional passivation layer 400 or the electrode layer 200A. In one embodiment, the piezoelectric device is a solid mounted resonator (SMR), having an acoustic mirror (Bragg reflector) 500, as shown in FIG. 2.

As can be seen in FIGS. 1 and 3, in certain embodiments a passivation layer 400 is deposited on a top surface of the substrate material 100. Additionally, a seed layer (not shown) is deposited onto electrode 200A, also sometimes referred to as a nucleation layer or a buffer layer. In one embodiment, the deposition of seed layer is an optional step. The purpose of this layer is to provide improved crystal growth and enhance crystal orientation for deposition of the functional piezoelectric layer. It is to be understood that the seed layer deposition, while referenced as a single step for purposes of simplicity and brevity, can include multiple seed layers deposited in succession. In one embodiment, the seed layer comprises AlN and is deposited at a film thickness of about 10-50 nm. The seed layer is deposited on the substrate via molecular beam epitaxy, chemical vapor deposition (CVD), pulsed laser deposition, reactive sputtering, or other appropriate methods that are known to those skilled in the art. In one example, an AlN seed layer can be deposited on a Si substrate, using an Al target in a sputtering chamber, at a temperature of 350° C. Base pressure of the sputtering chamber during deposition can be about 2×10⁻³ mbar. Gas flows introduced during sputtering can be for example, 10 sccm of Ar and 40 sccm of N₂.

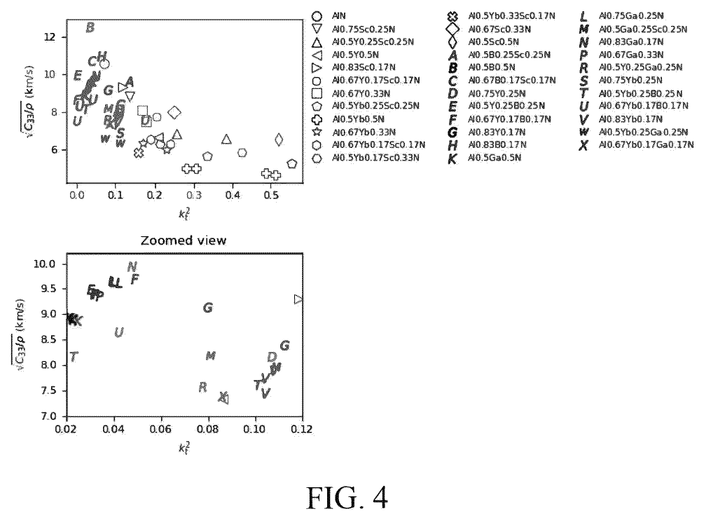

As shown in FIG. 4, kₜ² coefficient values and

$$\sqrt{\frac{{C}_{33}}{ρ}}$$

(km/s) values are graphed for different doping level percent variations of the proposed quaternary AlN alloys. The piezoelectric tensor and electromechanical coupling constant are computed with first principles calculations. The structural parameters are computed by density functional theory (DFT) as implemented in the Vienna ab-initio Simulation Package (VASP), using the standard set of Perdew-Burke-Ernzerhof (PBE) functional and plane augmented wave (PAW) pseudopotentials. In a case of multiple possible structures for a given composition, low-energy structures are selected with the assistance of an alloy cluster expansion. In the event multiple structures have similar energies of formation at a given composition, they are each plotted on the graph. The piezoelectric properties are computed with the density functional perturbation theory (DFPT) natively implemented in VASP. Since Cr-doped AlN is magnetic, to correctly reproduce the magnetic state, the piezoelectric tensor is calculated with the HSE hybrid functional.

The values depicted in FIG. 4 show a randomized pattern, with no clear observable trend lines. This suggest that the choice of dopant and doping level compositions are not predictable or obvious. This is partially due to the key values of kₜ² and vₛ being nonlinearly dependent on the underlying physical stress, dielectric, and piezoelectric tensors. Therefore, it may be expected that even if the underlying physics were to change linearly with doping, the KPI of interest, to wit kₜ² and vₛ, are much more difficult to predict.

Also disclosed are methods for fabricating a doped piezoelectric device, such as those shown in the embodiments of FIGS. 1-4. The method comprises the steps of providing a substrate and depositing a doped piezoelectric material on the substrate. The doped piezoelectric material comprises Al_{1-x-y}TₓM_{y}N, wherein 0<x+y<0.5, T is selected from Sc, Cr, Y, and Yb and M is selected from B, In, and Ga.

The doped piezoelectric material disclosed above can be deposited by sputter deposition, molecular beam epitaxy (MBE), or metalorganic chemical vapor deposition (MOCVD). In one embodiment, the sputter deposition process comprises single target sputtering or multi-target sputtering. In embodiments, the deposition of the piezoelectric layer results in a piezoelectric layer having an atomic content of T from 20-50% and an atomic content of M of 1-25%, and a maximum atomic content of T and M combined of 50% or less.

The piezoelectric layer can be deposited at a variety of thickness, including the in the range of about 50-2000 nm, or any range or value therebetween.

The substrate layer can comprise a material such Si (100) with a thickness of about 200 μm to 1.5 mm, or 380 μm to 725 μm, or 675 μm or 725 μm and a diameter in the area of 100 mm-300 mm, or 150 mm-200 mm, or 300 mm, or 100 mm. Optionally, an electrically insulating passivating layer can be deposited onto substrate 100. This layer can be comprised of, e.g., SiO₂ or SiN. An electrode layer 200A is then deposited. The electrode layer comprises, e.g., Mo, W, Al, or doped Si, and is deposited at thickness ranging from 0.05 to 0.5 um.

An optional seed layer, or buffer layer can be deposited on or below electrode 200A, prior to the deposition of the piezoelectric layer 300. The seed layer comprises AlN or doped AlN with graded composition layers, at total thickness of about 10-50 nm. Graded AlN seed, buffer or nucleation layers are known to those skilled in the art and will not be discussed in further details here. Their purpose is generally to relax strain or lattice mismatch and enhance crystal orientation for the main functional piezoelectric layer 300, deposited thereafter.

The deposition step of the piezoelectric layer 300, at a thickness of 50-2000 nm, can be deposited through deposition techniques including chemical vapor deposition MOCVD, molecular beam epitaxy (MBE), or sputter deposition.

In one embodiment, the deposition method is sputtering, including multi-target or single-target sputtering. In one embodiment, where multi-target sputter deposition is utilized, multiple separate targets are used, such as AlSc and GaN targets, in the sputtering system. The frequencies and pattern of the pulses can be used to achieve the desired crystal quality and composition (e.g., by using a higher sputtering power on one target as compared to the other). In another embodiment, all materials are combined into a single target, such as melting AlScGa or AlScGaN_{1-y} into a single alloy. The target's composition may not be identical to the final composition, due to the different mobility and sputtering yields of each element within the sputtering chamber, which yield loss or accumulation of atoms in the thin films as compared to the target. These effects can be adjusted for by increasing or lowering the corresponding atoms in the target. The piezoelectric film growth is monitored for a specific desired composition, using in-situ techniques or post-deposition analysis to ensure the desired target composition and properties. Similarly, deposition parameters (power, pressure, N2 or Ar partial pressures, wafer temperature, DC-bias, distance target to wafer, etc.) are adjusted as needed to achieve the desired film characteristics.

Once the piezoelectric layer 300 is deposited, the second electrode layer 200B can then be deposited thereon, also by sputtering or other deposition techniques well known in the art. An optional annealing step can further be conducted to improve crystal quality, optionally with an applied AC or DC electric field.

Also disclosed is an electrical filter comprising the film bulk acoustic resonator (FBAR) device described in the foregoing embodiments. In one embodiment, the electrical filter comprises a piezoelectric layer of Al_{1-x-y}TₓM_{y}N, wherein 0<x+y<0.5, wherein T is selected from Sc, Cr, Y, and Yb and M is selected from B, In, and Ga. It is to be understood that the piezoelectric devices disclosed in all prior embodiments can be incorporated in various embodiments related to an electrical filter, which comprises said devices. The previously described attributes of the piezoelectric devices disclosed are incorporated herein and not reiterated for purposes of brevity.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A piezoelectric device, comprising:
a substrate material;
a piezoelectric layer comprising Al_{1-x-y}TₓM_{y}N, wherein 0<x+y<0.5, wherein T is selected from Sc, Cr, Y, and Yb and M is selected from B, In, and Ga;
a first electrode layer; and
a second electrode layer.

2. The piezoelectric device of claim 1, wherein the piezoelectric layer comprises a wurtzite crystal structure, wherein x<0.5 and y<0.5.

3. The piezoelectric device of claim 1, wherein an atomic content of T ranges from 10-50% and an atomic content of M ranges from 1-25%, and a maximum atomic content of T and M combined is 50% or less.

4. The piezoelectric device of claim 1, wherein x and y are equal.

5. The piezoelectric device of claim 1, wherein the piezoelectric layer has an electromechanical coupling constant, kₜ², wherein kₜ² is about 0.1-0.8.

6. The piezoelectric device of claim 1, wherein the piezoelectric layer has a
$$\sqrt{\frac{{C}_{33}}{ρ}}$$
value of about 7,000-10,000 m/s.

7. The piezoelectric device of claim 1, wherein the piezoelectric layer comprises a stiffness coefficient, C₃₃, of about 100-400 GPa.

8. The piezoelectric device of claim 1, wherein the piezoelectric layer comprises Al_{1-x-y}YₓB_{y}N and/or Al_{1-x-y}CrₓB_{y}N and/or Al_{1-x-y}ScₓB_{y}N.

9. The piezoelectric device of claim 1, wherein the piezoelectric device is a film bulk acoustic resonator (FBAR) device.

10. The piezoelectric device of claim 1, wherein the piezoelectric layer has a thickness of about 50-2000 nm.

11. The piezoelectric device of claim 1, further comprising a Bragg reflector structure.

12. The piezoelectric device of claim 1, wherein the device is a membrane FBAR, an air gap FBAR, or a solidly mounted resonator (SMR).

13. A method of fabricating a doped piezoelectric device comprising:
providing a substrate; and
depositing a doped piezoelectric material;
wherein the doped piezoelectric material comprises Al_{1-x-y}TₓM_{y}N, wherein 0<x+y<0.5, T is selected from Sc, Cr, Y, and Yb and M is selected from B, In, and Ga.

14. The method of claim 13, wherein the doped piezoelectric material is deposited by sputter deposition process, molecular beam epitaxy (MBE), chemical vapor deposition (CVD) or metal-organic chemical vapor deposition (MOCVD).

15. The method of claim 14, wherein the sputter deposition process comprises single target sputtering or multi-target sputtering.

16. The method of claim 13, wherein deposition of the piezoelectric layer results in a piezoelectric layer having an atomic content of T from 10-50% and an atomic content of M of 1-25%, and a maximum atomic content of T and M combined of 50% or less.

17. The method of claim 13, wherein the piezoelectric layer is deposited at a thickness of 50-2000 nm.

18. The method of claim 13, wherein the piezoelectric layer comprises Al_{1-x-y}YₓB_{y}N and/or Al_{1-x-y}CrₓB_{y}N and/or Al_{1-x-y}ScₓB_{y}N.

19. The method of claim 13, wherein the piezoelectric device is a film bulk acoustic resonator (FBAR) device.

20. An electrical filter comprising:
a film bulk acoustic resonator (FBAR) device, which comprises:
a piezoelectric layer comprising Al_{1-x-y}TₓM_{y}N, wherein 0<x+y<0.5, wherein T is selected from Sc, Cr, Y, and Yb and M is selected from B, In, and Ga.
